(19) United States
(12) Patent Application Publication
(10) Pub. No.: US 2008/0087995 A1
(43) Pub. Date: Apr. 17, 2008

(54) FLEXIBLE FILM SEMICONDUCTOR PACKAGE AND METHOD FOR MANUFACTURING THE SAME

(75) Inventors: Se-Young YANG, Seoul (KR); Wang-Ju LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/874,107

(22) Filed: Oct. 17, 2007

(30) Foreign Application Priority Data
Oct. 17, 2006 (KR) 10-2006-100939

(51) Int. Cl. H01L 23/495

(52) U.S. Cl. 257/676; 257/E23.031

(57) ABSTRACT

Provided are a semiconductor package and a manufacturing method thereof. The semiconductor package includes a flexible film with a film wire region formed of a film substrate region on which a semiconductor chip is mounted, and a plurality of sub film wires branching and extending from the film substrate region and electrically connected to the semiconductor chip. A plurality of external contact terminals arranged on the outer surface of the flexible film and electrically connected to the semiconductor chip is further included. Also included is a plurality of conductive patterns having first pads disposed in the flexible film, arranged on the film substrate region, and electrically connected to one of the plurality of external contact terminals; and second pads arranged on the film wire region and electrically connected to the semiconductor chip.

### CROSS-REFERENCE TO RELATED APPLICATIONS

This U.S. non-provisional patent application claims priority under 35 U.S.C. § 119 to Korean Patent Application No. 10-2006-100939, filed on Oct. 17, 2006, the entire contents of which are hereby incorporated by reference.

### BACKGROUND

1. Technical Field

The present invention relates to a flexible film for semiconductor packages, a semiconductor package employing the flexible film, and a method for manufacturing the semiconductor package, and more particularly, to a semiconductor package employing a flexible film that functions doubly as a substrate and a wire, and to a manufacturing method for a semiconductor package employing a flexible film.

2. Description of the Related Art

Generally, in the structure of a semiconductor package, a semiconductor chip is bonded to a substrate, a bonding wire electrically connects the semiconductor chip to the substrate, and an insulator protects the bonding wire and the semiconductor chip from external moisture and/or impurities. A semiconductor package further includes a solder ball array attached to the substrate. The solder balls function as terminals for relaying inputs and outputs from and to the outside. Pads for electrically connecting a semiconductor chip to bonding wires are provided at the edges or center of the chip.

FIG. 1 is a sectional view of a conventional semiconductor chip package. Referring to FIG. 1, a conventional chip-on-board (COB) type semiconductor package 10 has a first semiconductor chip 13 mounted on a substrate 11. A plurality of pads 14 is formed on an active surface 13a of the first semiconductor chip 13, and a plurality of pads 12 are also formed on the upper surface 11a of the substrate 11. The pads 12 and 14 are connected by a plurality of bonding wires 17 to electrically connect the substrate 11 to the first semiconductor chip 13. Selectively, a second semiconductor chip 15 may be stacked on the first semiconductor chip 13. A plurality of pads 16 is formed on an active surface 15a of the second semiconductor chip 15, and the plurality of pads 16 is electrically connected to the plurality of pads 12 through a plurality of bonding wires 19.

However, because the substrate 11 in a typical semiconductor package 10 is a rigid substrate, even when the thickness of the substrate 11 is reduced, warping of the first and second semiconductor chips 13 and 15 and the substrate 11 occurs during manufacturing or actual use, due to a coefficient of thermal expansion (CTE) mismatch between the first and second semiconductor chips 13 and 15 and the substrate 11. Warping of the first and second semiconductor chips 13 and 15 and the substrate 11 can cause various problems during assembly or actual use of the semiconductor package 10. Moreover, electrical connections for the substrate 11 and the first and second semiconductor chips 13 and 15 are provided by the bonding wires 17 and 19. When the number of bonding wires 17 and 19 is excessive or the gaps between the bonding wires 17 and 19 are too small, wire sweeping between contacting wires 17 and 19 during a manufacturing process (a molding process, for instance) can easily induce shorting defects.

Also, if the first and second semiconductor chips 13 and 15 are stacked, a region 20 in which the bonding wire 17 contacts an inactive surface 15b of the second semiconductor chip 15 can be formed. Such a contacting region 20 can result in a functional defect of the semiconductor package 10. To overcome this limitation, a distance (d) between the first and second semiconductor chips 13 and 15, that is, a bond line thickness, may be increased to minimize the possibility of contact between the bonding wires 17 and the second semiconductor chip 15. However, when the distance (d) between the first and second semiconductor chips 13 and 15 is increased, the overall package height increases and so forming the semiconductor package 10 having a reduced overall height is problematic. The present invention addresses these and other disadvantages of the conventional art.

### SUMMARY

The present invention provides a flexible film, a semiconductor package employing the flexible film, and a method for manufacturing the same. The flexible film of the present invention is used as both a substrate and bonding wires.

Embodiments of the present invention provide flexible films including: a first region configured to have a semiconductor chip mounted thereon; a second region including a plurality of portions extending from the first region; and a plurality of conductive patterns extending toward the first region and the second region, wherein a first end of the conductive patterns extending toward the first region is configured to be electrically connected to external contact terminals, and a second end of the conductive patterns extending toward the second region is configured to be electrically connected to the semiconductor chip.

According to the present invention, a flexible film performs the functions of both a substrate and a wire. Accordingly, the occurrence of warping due to CTE differences and surface stress is minimized, and the possibility of wire sweeping occurrences is minimized. When a plurality of semiconductor chips are stacked, contact between wires and bottom surfaces of semiconductor chips does not occur, so that a small bond line thickness (BLT) can be realized. Moreover, a low cost and an easy fabrication process can also be realized.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a sectional view of a conventional semiconductor chip package;

FIGS. 2A through 2C are sectional views of stages in a manufacturing process for a semiconductor package according to an embodiment of the present invention;

FIG. 2D is a perspective view of a semiconductor package according to an embodiment of the present invention;

FIG. 3A is a plan view of a flexible film according to an embodiment of the present invention;

FIG. 3B is a sectional view of the flexible film in FIG. 3A taken along line I-I;

FIGS. 4A through 4E are sectional views of stages in a manufacturing process for a semiconductor package according to another embodiment of the present invention;

FIG. 4F is a perspective view of a semiconductor package according to another embodiment of the present invention;

FIG. 5A is a sectional view of a flexible film according to an embodiment of the present invention;

FIG. 5B is a sectional view showing a portion of a flexible film according to another embodiment of the present invention; and

FIG. 6 is a plan view of a flexible film according to still another embodiment of the present invention.

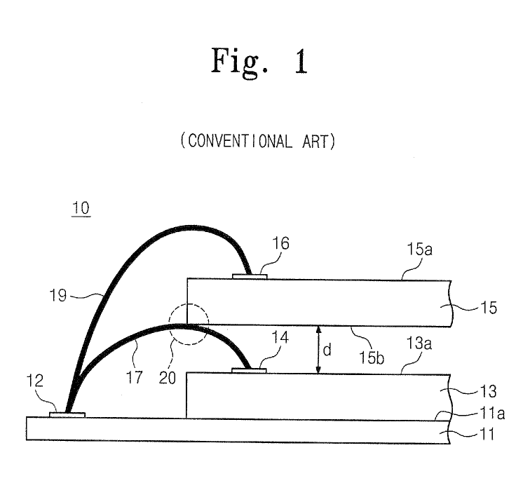

### DETAILED DESCRIPTION

Preferred embodiments of the flexible film, semiconductor package, and the method for manufacturing the same according to the present invention will be described below in more detail with reference to the accompanying drawings.

The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

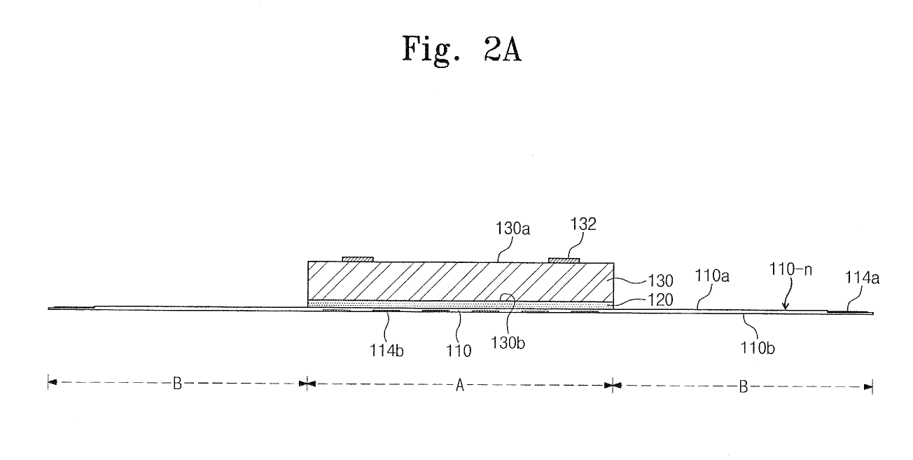

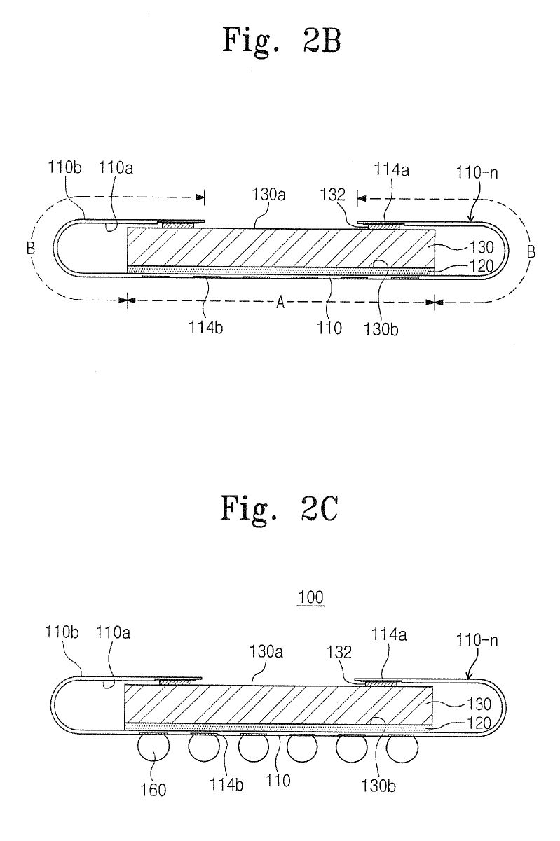

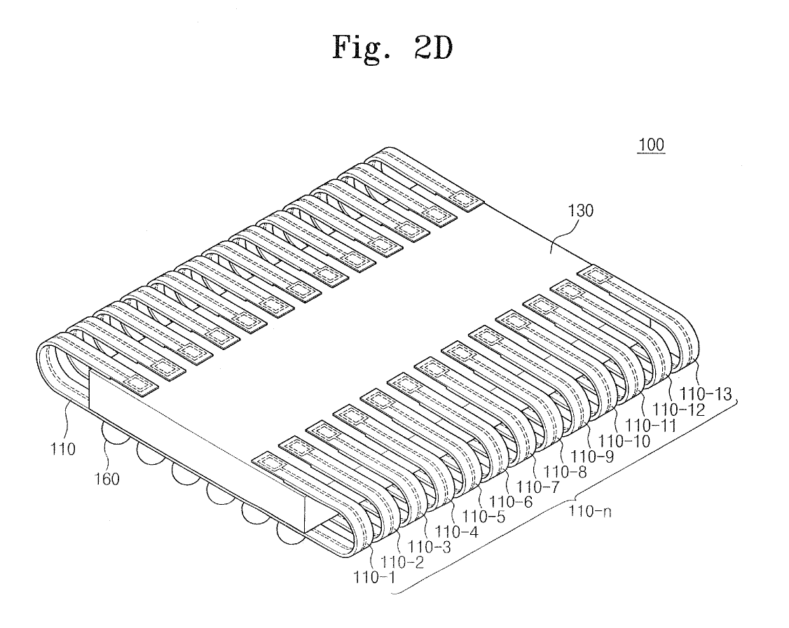

FIGS. 2A through 2C are sectional views of stages in a manufacturing process for a semiconductor package according to an embodiment of the present invention, and FIG. 2D is a perspective view of a semiconductor package according to an embodiment of the present invention.

Referring to FIG. 2A, a semiconductor chip 130 and a film 110 are provided. The semiconductor chip 130 has an active surface 130a with a plurality of chip pads 132 formed thereon and an inactive surface 130b opposite to the active surface 130a. The plurality of chip pads 132 may be formed at the edge of the semiconductor chip 130 or at the center of the semiconductor chip 130, depending on the design. The film 110, which functions both as a substrate and a wire, may be a flexible film. The film 110 has an upper surface 110a to which the semiconductor chip 130 is attached and a lower surface 110b on the opposite side. Upper pads 114a, functioning as pads connected electrically to the semiconductor chip 130, are disposed on the upper surface 110a of the film 110; and lower pads 114b, to which external contact terminals are attached, are disposed on the lower surface 110b of the film 110. As described below, the upper and lower pads 114a and 114b are portions of a conductive pattern.

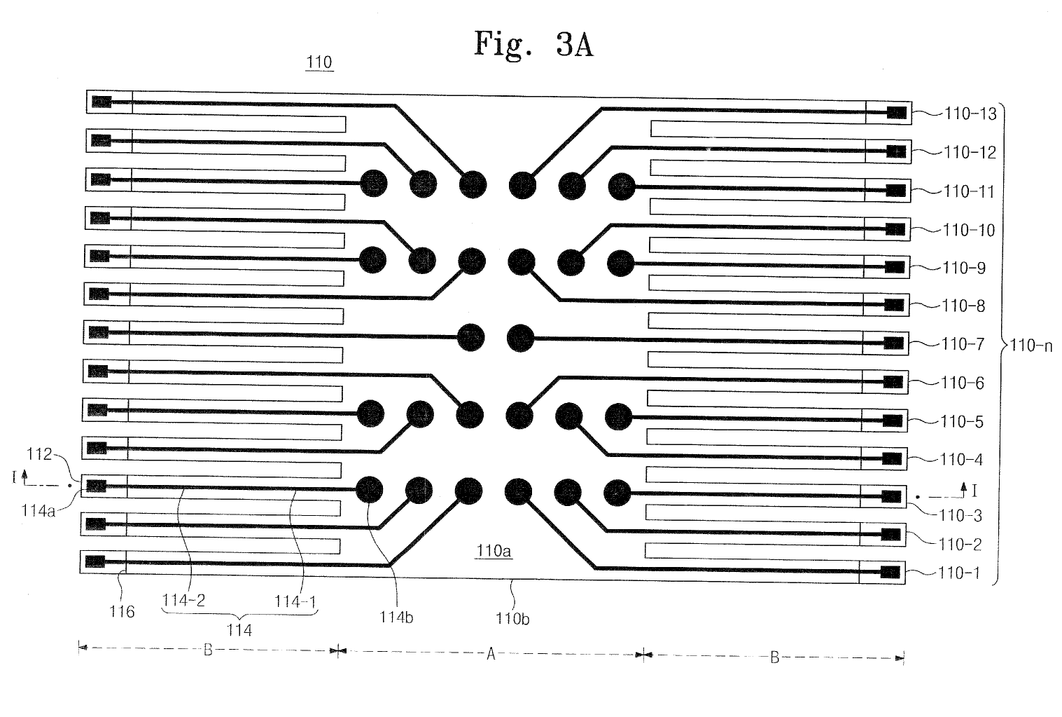

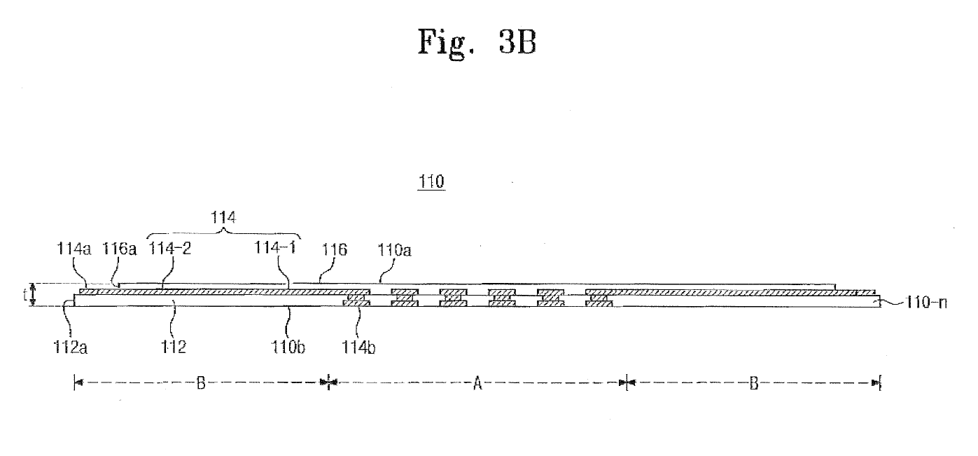

FIG. 3A is a plan view of a flexible film according to an embodiment of the present invention, and FIG. 3B is a sectional view of the flexible film in FIG. 3A taken along line I-I.

Referring to FIGS. 3A and 3B, the film 110 is a flexible thin film with a thickness (t) of approximately 200 micrometers or less. The film 110 has a conductive pattern 114 inserted between an insulating lower layer 112 and an insulating upper layer 116. The film 110 can be divided into a film substrate region A functioning as a substrate on which a semiconductor chip is mounted, and a film wire region B functioning as a bonding wire connected to a pad of a semiconductor chip.

The upper surface of the upper layer 116 is defined as the upper surface 110a of the film 110, and the lower surface of the lower layer 112 is defined as the lower surface 110b of the film 110. The lower layer 112 and the upper layer 116 may be formed of, for example, a solder resist or other types of insulating polymers. The conductive pattern 114 is formed of a metal such as copper or gold in order to function as an electrical circuit. The conductive pattern 114 may be divided into a first sub pattern 114-1 that extends toward the film substrate region A, and a second sub pattern 114-2 that extends toward the film wire region B. One end of the first sub pattern 114-1 is disposed in the film substrate region A and is connected to the lower pattern 114b to which an external contact terminal is attached, and one end of the second sub pattern 114-2 is disposed in the film wire region B and is connected to the upper pads 114a that are connected to the pads 132 (in FIG. 2A) of the semiconductor chip.

One end 116a of the upper layer 116 does not extend to the end 112a of the lower layer 112. Accordingly, the upper layer 116 is not formed on the upper surfaces of the upper pads 114a, so that the upper pads 114a are exposed to the outside. The film wire region B has a film wire 110-n having the upper pads 114a. The film wire 110-n is formed of a plurality of sub film wires (110-1, 110-2 . . . 110-12, 110-13).

Referring again to FIG. 2A, as a chip die attach process, the semiconductor chip 130 is mounted on the film substrate region A with an adhesive 120 interposed between so that the inactive surface 130b of the semiconductor chip 130 faces the upper surface 110a of the film 110. That is, the semiconductor chip 130 mounted on the film 110 is called a chip-on-film (COF) structure. The adhesive 120 may be any type of adhesive including liquid and film-type adhesives.

Referring to FIG. 2B, as a chip film wiring process, the film wire 110-n of the film wire region B is bent so that the upper pads 114a are put in contact with the chip pads 132 to electrically connect the semiconductor chip 130 to the film 110. The connections between the upper pads 114a and the chip pads 132 may be made using adhesive that is commonly known, such as anisotropic conductive film (ACF), non-conductive paste (NCP), etc. Any one of widely known methods, for example metallurgical bonding, ultrasonic bonding, thermosonic bonding, thermo-compressive-thermosonic bonding, soldering and the like, may be used to connect the upper pads 114a to the chip pads 132.

Referring to FIG. 2C, as a solder ball attach process, a plurality of solder balls 160, which are commonly used as external contact terminals, may be attached to the lower pads 114b. Thus, a semiconductor package 100 is formed as a single stack package.

Referring to FIG. 2D, the semiconductor chip 130 is mounted on the film 110. In addition, the plurality of sub film wires 110-1, . . . , 110-13 are electrically connected with the semiconductor chip 130. Consequently, the film 110 functions both as a substrate and as a bonding wire.

A semiconductor package 100 formed using the processes described above has a flexible film 110 performing the function of a substrate. Therefore, even when the semiconductor chip 130 is a hard body, because the film 110 is flexible, the chance of warping of the semiconductor chip 130 and the film 110 due to differences in CTE is minimized. Moreover, the metal pattern 114 enclosed by insulating upper and lower layers 112 and 116 is used as bonding wires, and so there is no possibility of contact occurring between the metal patterns 114, thereby minimizing the possibility of wire sweeping occurrences. Furthermore, because a very thin film 110 is used as a substrate and bonding wire, the semiconductor package 100 is very thin overall.

### ANOTHER EMBODIMENT

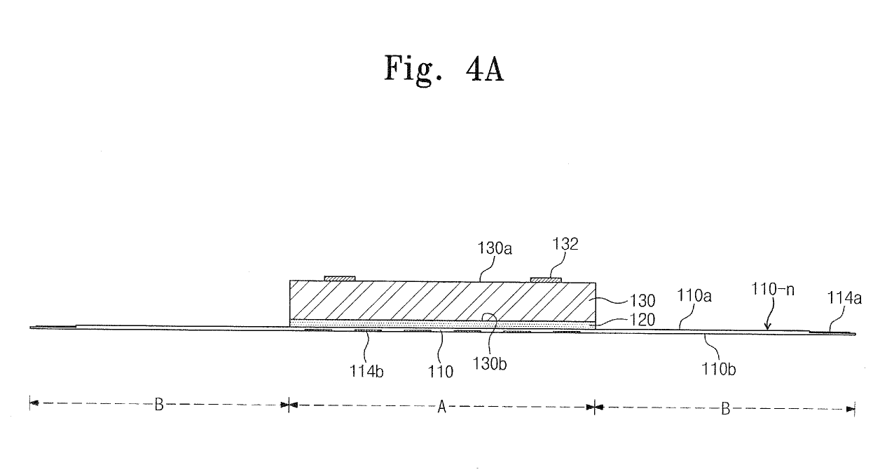

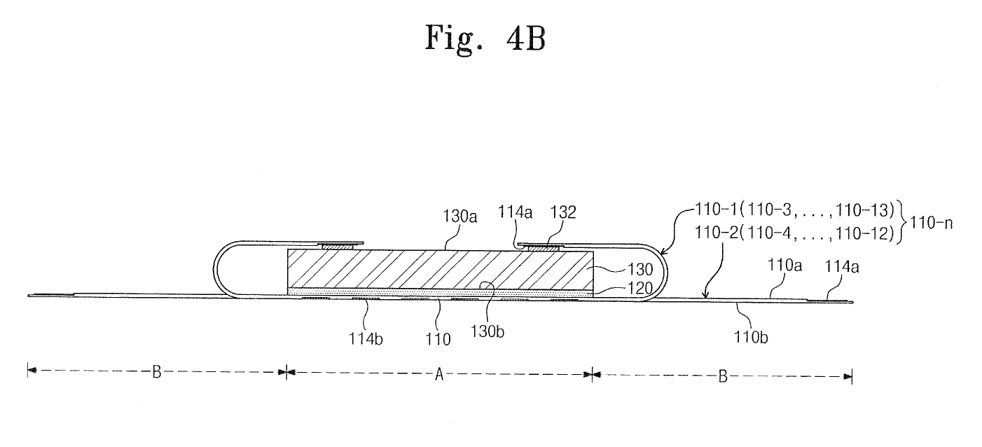

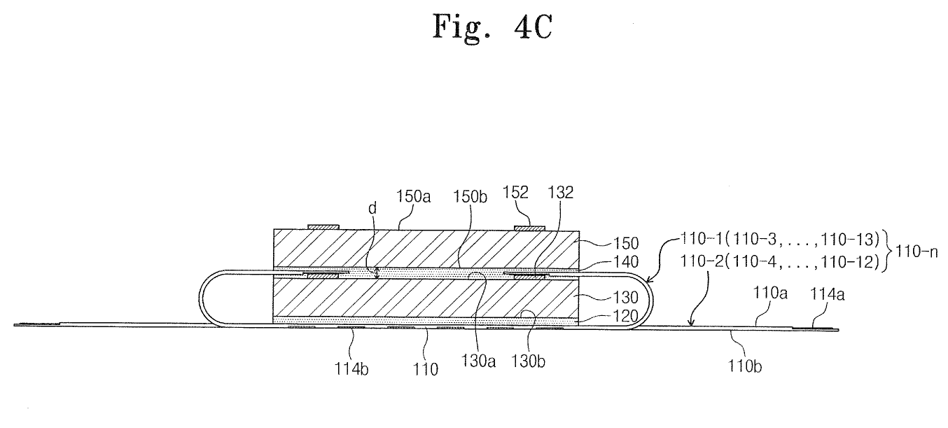

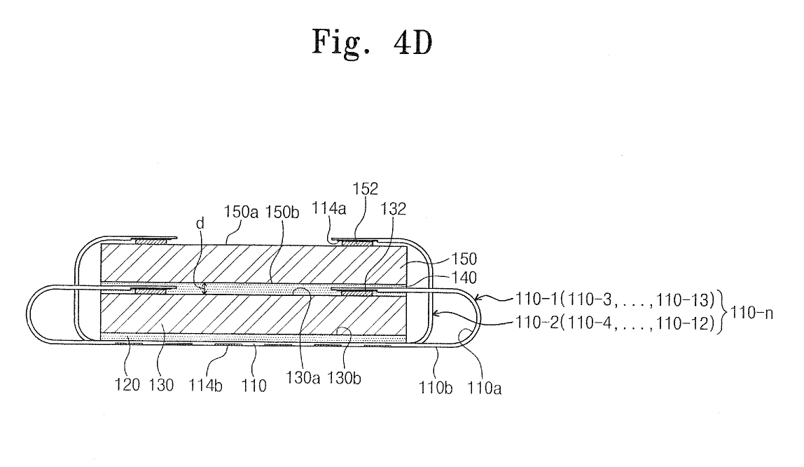

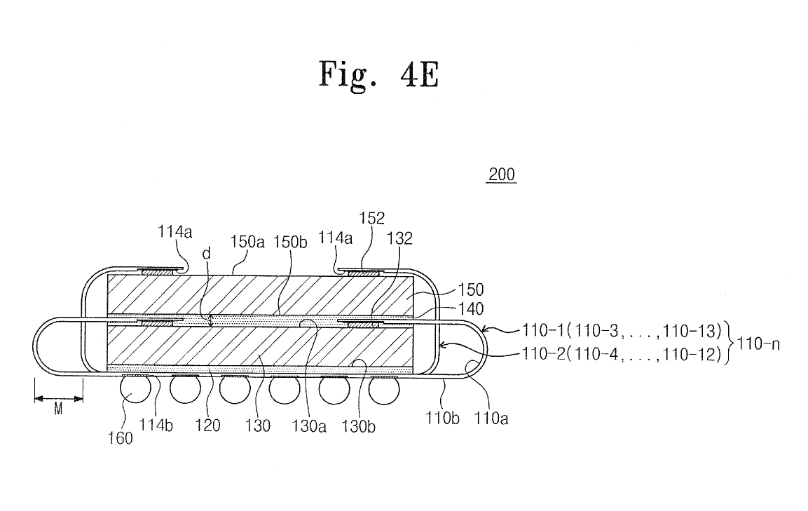

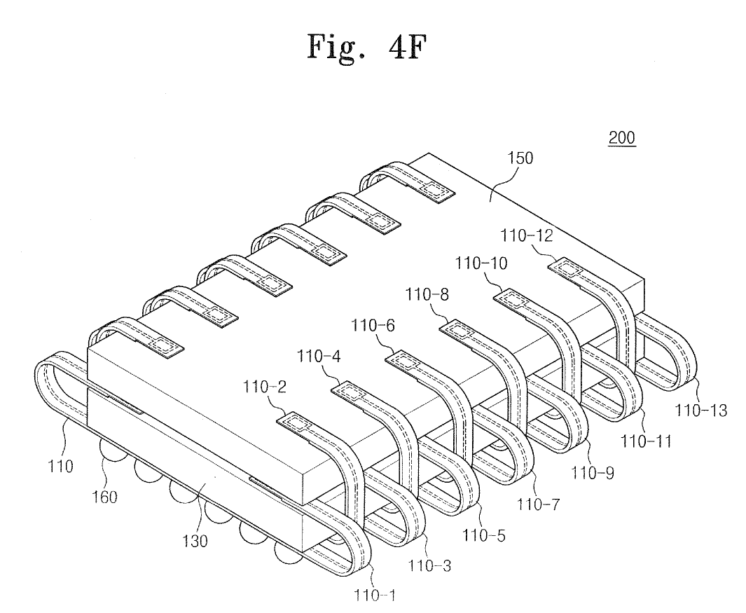

FIGS. 4A through 4E are sectional views of stages in a manufacturing process for a semiconductor package according to another embodiment of the present invention, and FIG. 4F is a perspective view of a semiconductor package according to another embodiment of the present invention.

Referring to FIG. 4A, as a first chip die attach process, a first semiconductor chip 130 is mounted on a film 110 with an adhesive 120 interposed therebetween, so that an inactive surface 130b of the semiconductor chip 130 faces the upper surface 110a of the film 110. The film 110, the adhesive 120, and the first semiconductor chip 130 can be described in the same manner as the description given with reference to FIGS. 2A, 3A, and 3B.

Referring again to FIG. 3A, odd-numbered sub film wires 110-1, 110-3, . . . 110-11, 110-13, for example, may be used as bonding wires to electrically connect the film 110 with the first semiconductor chip 130 (in FIG. 4D), and the even-numbered sub film wires 110-2, 110-4, . . . 110-10, 110-12, for example, may be used as bonding wires to electrically connect a second semiconductor chip 150 (in FIG. 4D) stacked on the first semiconductor chip 130 (in FIG. 4D) with the film 110.

Referring to FIG. 4B, as a first film wiring process, with the exception of the even-numbered sub film wires 110-2, 110-4, . . . 110-12 of the film wire 110-n, the odd-numbered sub film wires 110-1, 110-3, . . . 110-13 are bent to bring into contact the chip pads 132 of the first semiconductor chip 130 and the upper pads 114a. Thus, the first semiconductor chip 130 and the film 110 are electrically connected to each other.

Referring to FIG. 4C, as a second chip die attach process, the second semiconductor chip 150 is mounted on the active surface 130a of the first semiconductor chip 130 with an adhesive 140 interposed therebetween. The second semiconductor chip 150 has an active surface 150a and an inactive surface 150b, and the active surface 150a has a plurality of chip pads 152 arranged thereon. The adhesive 140 may include any type of adhesive including liquid and film-type adhesives.

Because very thin sub film wires 110-1, 110-3, . . . 110-13 are used, a distance (d) between the first and second semiconductor chips 130 and 150, that is, a bond line thickness (BLT) can be very short. Even when the distance (d) between the first and second semiconductor chips 130 and 150 is very short, as shown in FIG. 3B, because the metal pattern 114 is enclosed by the insulating upper and lower layers 112 and 116, there is no chance of contact occurring between an inactive surface 150b of the second semiconductor chip 150 and the metal pattern 114. Accordingly, a larger number of semiconductor chips can be stacked with small bond line thicknesses.

Referring to FIG. 4D, as a second chip film wiring process, the even-numbered sub film wires 110-2, 110-4, . . . 110-12 are bent to contact the chip pads 152 of the second semiconductor chip 150 with the upper pads 114a. Therefore, the second semiconductor chip 150 and the film 110 are electrically connected to each other.

Referring to FIG. 4E, as a solder ball attach process, a plurality of solder balls 160, as external contact terminals, may be attached to the lower pads 114b. Therefore, the semiconductor package 200 is formed as a dual stack package.

Referring to FIG. 4F, the film 110 functions as a substrate in the semiconductor package 200, the odd-numbered sub film wires 110-1, . . . 110-13 function as bonding wires to electrically connect the first semiconductor chip 130 and the film 110, and the even-numbered sub film wires 110-2, . . . 110-12 function as bonding wires to electrically connect the second semiconductor chip 150 to the film 110.

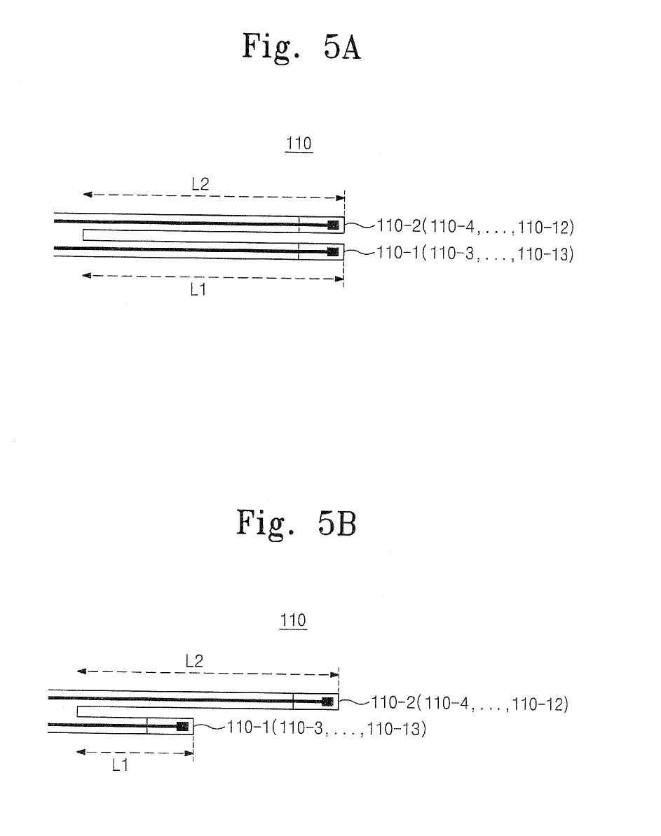

FIG. 5A and FIG. 5B are sectional views showing portions of a flexible film according to an embodiment of the present invention.

Referring to FIG. 5A, when the length L₁ of the odd-numbered sub film wires 110-1, 110-3, . . . 110-13 is the same as the length L₂ of the even-numbered sub film wires 110-2, 110-4, . . . 110-12, as shown in FIG. 4E, the odd-numbered sub film wires 110-1, 110-3, . . . 110-13 protrude outward from the semiconductor package 200 by a predetermined distance (M) more than the even-numbered sub film wires 110-2, 110-4, . . . 110-12. When this distance (M) is removed, the width of the semiconductor package 200 may be reduced. Therefore, as shown in FIG. 5B, it is preferable that the length L₁ of the odd-numbered sub film wires 110-1, 110-3, . . . 110-13 is shorter than the length L₂ of the even-numbered sub film wires 110-2, 110-4, . . . 110-12.

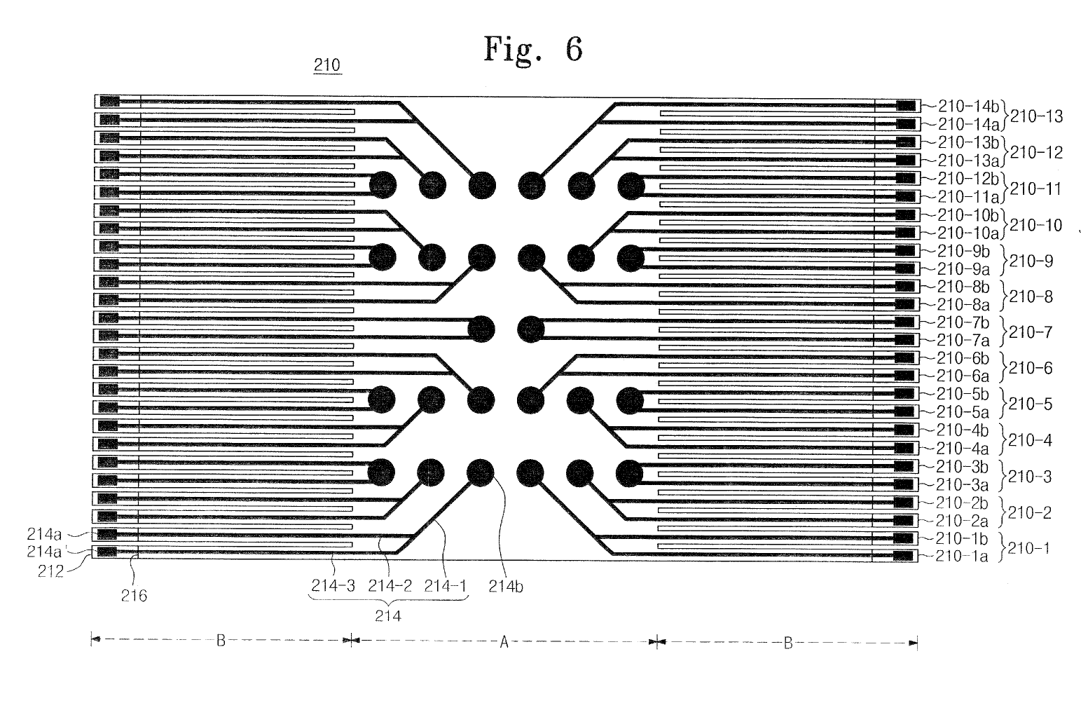

FIG. 6 is a plan view of a flexible film according to another embodiment of the present invention.

Referring to FIG. 6, the film 210 in another embodiment of the present invention, like the film 110 shown in FIGS. 3A and 3B, may be a flexible film having an insulating lower layer 212 and an insulating upper layer 216 that are stacked, with a conductive pattern 214 interposed between the upper and lower layers 212 and 216. The film 210 is divided into a film substrate region A that functions as a substrate, and a film wire region B that functions as a bonding wire. The conductive pattern 214 comprises a first sub pattern 214-1 that extends toward the film substrate region A, a second sub pattern 214-2 and a third sub pattern 214-3 that branch from the first sub pattern 214-1 and extend toward the film wire region B. An end of the first sub pattern 214-1 is disposed on the film substrate region A and is connected to lower pads 214b on which external contact terminals 160 (in FIG. 4F) are attached. The second and third sub patterns 214-2 and 214-3 each have one end disposed on the film wire region B, and are connected to upper pads 214a and 214a′ connected respectively to the semiconductor chips 130 and 150 (in FIG. 4E). That is, the film 210 has two upper pads 214a and 214a′ that are extended from a single lower pad 214b, and is thus suitable for use, for example, in a dual stack package in which semiconductor chips in upper and lower positions share one external contact terminal.

For example, odd-numbered sub film wires 210-1, 210-3, . . . 210-11, 210-13 are connected to a lower semiconductor chip 130 (in FIG. 4F), and even-numbered film wires 210-2, 210-4, . . . 210-10, 210-12 are connected to an upper semiconductor chip 150 (in FIG. 4F). A first sub film wire 210-1 of the odd-numbered sub film wires 210-1, 210-3, . . . 210-11, 210-13 is divided into a sub film wire 210-1a electrically connected to the lower semiconductor chip 130 (in FIG. 4F), and a sub film wire 210-1b electrically connected to the upper semiconductor chip 150 (in FIG. 4F). That is, the first sub film wire 210-1 is connected to two semiconductor chips 130 and 150, and the two semiconductor chips 130 and 150 share one external contact terminal connected to the first sub film wire 210-1. As shown in FIGS. 5A and 5B, the length of the sub film wire 210-1a may be equal to or shorter than the length of the sub film wire 210-1b. The above description of the first sub film wire 210-1 applies equally to other odd-numbered sub film wires 210-3, . . . 210-11, 210-13.

The second sub film wire 210-2 of the even-numbered sub film wires 210-2, 210-4, . . . 210-10, 210-12 is divided into a sub film wire 210-2a electrically connected to the lower semiconductor chip 130 (in FIG. 4F), and a sub film wire 210-2b that is electrically connected to the upper semiconductor chip 150 (in FIG. 4F). The second sub film wire 210-2 is connected to two semiconductor chips 130 and 150, and the two semiconductor chips 130 and 150 share one external contact terminal connected to the second sub film wire 210-2. Again, as shown in FIGS. 5A and 5B, the length of the sub film wire 210-2a may be equal to or less than the length of the sub film wire 210-2b. The above description of the second sub film wire 210-2 equally applies to other even-numbered sub film wires 210-4, . . . 210-10, 210-12.

As described in detail above, according to some embodiments of the present invention, a flexible film functions as a substrate and a wire at the same time, so that warping and surface tension caused by CTE differences is minimized, and the possibility of wire sweeping is minimized, thus improving the electrical characteristics of a semiconductor package. Moreover, when a plurality of chips are stacked, wires do not contact rear surfaces of chips, and a small bond line thickness can be realized. Also, manufacturing cost can be reduced, and the manufacturing process can be simplified.

Embodiments of the present invention provide flexible films including: a first region configured to have a semiconductor chip mounted thereon; a second region including a plurality of portions extending from the first region; and a plurality of conductive patterns extending toward the first region and the second region, wherein a first end of the conductive patterns extending toward the first region is configured to be electrically connected to external contact terminals, and a second end of the conductive patterns extending toward the second region is configured to be electrically connected to the semiconductor chip.

In some embodiments, the flexible film may further include an insulating thin film enclosing the plurality of conductive patterns and including an upper surface and a lower surface, wherein the upper surface is configured to have the semiconductor chip mounted thereon, and the lower surface is configured to have the external contact terminals attached thereto.

In other embodiments, the first end may be a first pad disposed in the first region and configured to be electrically connected to the external contact terminals, and the second end may be a second pad disposed in the second region and configured to be electrically connected to the semiconductor chip.

In still other embodiments, each of the conductive patterns may include a first sub pattern extending toward the first region and having the first end, and a second sub pattern extending from the first sub pattern and extending toward the second region and having the second end.

In even other embodiments, each of the conductive patterns may include a first sub pattern extending toward the first region and having the first end, and a plurality of second sub patterns branching and extending from the first sub pattern and extending toward the second region, and having the second end respectively.

In yet other embodiments, the plurality of divided portions of the second region may have the same or different lengths. The plurality of portions may comprise a first set of portions having a first length and a second set of portions having a second length, the second length longer than the first length.

In other embodiments of the present invention, a semiconductor package includes: a semiconductor chip; a flexible film including a film substrate region on which the semiconductor chip is mounted, and a film wire region branching and extending from the film substrate region into a plurality of sub film wires; a plurality of external contact terminals arranged on the film substrate region at an outer surface of the flexible film; and a plurality of conductive patterns disposed in the flexible film, and respectively having first pads arranged on the film substrate region and electrically connected to one of the external contact terminals, and second pads arranged on the film wire region and electrically connected to the semiconductor chip.

In some embodiments, the flexible film further may include an insulating upper layer and an insulating lower layer respectively disposed at a top and bottom of the plurality of conductive patterns, wherein the semiconductor chip may be mounted on an upper surface of the upper layer.

In other embodiments, each of the conductive patterns may include a first sub pattern extended toward the film substrate region, and a second sub pattern extending from the first sub pattern and toward the film wire region. One end of the first sub pattern may include the first pads, and one end of the second sub pattern may include the second pads.

In further embodiments, the semiconductor chip may include a first semiconductor chip mounted on the film substrate region, and a second semiconductor chip stacked on the first semiconductor chip; and the plurality of sub film wires may include first sub film wires electrically connected to the first semiconductor chip, and second sub film wires electrically connected to the second semiconductor chip.

In still further embodiments, each of the conductive patterns may include a first sub pattern extended toward the film substrate region, and a second sub pattern extending from the first sub pattern and toward one of the first and second sub film wires.

In yet further embodiments, each of the conductive patterns may include a first sub pattern extending toward the film substrate region, and a second sub pattern extending from the first sub pattern and branching and extending toward both the first and second sub film wires. The first and second semiconductor chips respectively connected electrically to the first and second sub film wires may share one of the external contact terminals.

In even further embodiments, the first sub film wire may have a shorter length than the second sub film wire.

In still other embodiments of the present invention, methods for manufacturing a semiconductor package, include: providing a flexible film including a film substrate region and a film wire region with a plurality of sub film wires branching and extending from the film substrate region; mounting a semiconductor chip on an upper surface of the flexible film; electrically connecting the plurality of sub film wires to the semiconductor chip; and attaching a plurality of external contact terminals to a lower surface of the flexible film.

In other embodiments, the flexible film may have a conductive pattern enclosed by an insulating layer, a plurality of lower pads formed of a portion of the conductive patterns on the film substrate region, and an upper pad formed of another portion of the conductive patterns on each of the sub film wires.

In still other embodiments, the method may further include: electrically connecting the plurality of sub film wires to the semiconductor chip; and electrically connecting the upper pads to an active surface of the semiconductor chip.

In further embodiments, the mounting of the semiconductor chip on the upper surface of the flexible film may include: mounting a first semiconductor chip by attaching an inactive surface thereof on the film substrate region with a first adhesive interposed therebetween; and mounting a second semiconductor chip by attaching an inactive surface thereof on an active surface of the first semiconductor chip with a second adhesive interposed therebetween.

In still further embodiments, the electrical connecting of the plurality of sub film wires to the semiconductor chip may include: electrically connecting a portion of the sub film wires to the active surface of the first semiconductor chip; and electrically connecting another portion of the sub film wires to an active surface of the second semiconductor chip.

In even further embodiments, the portion of the sub film wires electrically connected to the first semiconductor chip and the portion of the sub film wires electrically connected to the second semiconductor chip may share one of the external contact terminals.

In additionally further embodiments, the portion of the sub film wires electrically connected to the first semiconductor chip may be shorter in length than the portion of the sub film wires electrically connected to the second semiconductor chip.

According to the present invention, a flexible film performs the functions of both a substrate and a wire. Accordingly, the occurrence of warping due to CTE differences and surface stress is minimized, and the possibility of wire sweeping occurrences is also minimized. When a plurality of semiconductor chips are stacked, contact between wires and bottom surfaces of semiconductor chips does not occur, so that a small bond line thickness (BLT) can be realized. Moreover, a low cost and an easy fabrication process can also be realized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A flexible film comprising:
a first region configured to have a semiconductor chip mounted thereon;
a second region including a plurality of portions extending from the first region; and
a plurality of conductive patterns, each of the conductive patterns including a first end disposed in the first region and a second end disposed in the second region, wherein the first end is configured to electrically connect to external contact terminals, and the second end is configured to electrically connect to the semiconductor chip.

2. The flexible film of claim 1, further comprising an insulating thin film substantially enclosing the plurality of conductive patterns and including an upper surface and a lower surface, wherein the upper surface is configured to have the semiconductor chip mounted thereon, and the lower surface is configured to have the external contact terminals attached thereto.

3. The flexible film of claim 2, wherein the first end is a first pad disposed in the first region and configured to be electrically connected to the external contact terminals, and the second end is a second pad disposed in the second region and configured to be electrically connected to the semiconductor chip.

4. The flexible film of claim 2, wherein each of the conductive patterns includes a first sub pattern extending toward the first region and having the first end; and a second sub pattern extending from the first sub pattern toward the second region and having the second end.

5. The flexible film of claim 2, wherein each of the conductive patterns includes a first sub pattern extending toward the first region and having the first end; and a plurality of second sub patterns branching from the first sub pattern, and extending toward the second region, each having the second end respectively.

6. The flexible film of claim 1, wherein the plurality of portions of the second region comprise a plurality of film wires configured to be connected to the semiconductor chip, the film wires having the same or different lengths.

7. The flexible film of claim 6, wherein the plurality of portions comprises a first set of portions having a first length and a second set of portions having a second length, the second length longer than the first length.

8. A semiconductor package comprising:
a semiconductor chip;
a flexible film including a film substrate region on which the semiconductor chip is mounted, and a film wire region branching and extending from the film substrate region, the film wire region having a plurality of sub film wires;
a plurality of external contact terminals arranged on the film substrate region; and
a plurality of conductive patterns disposed in the flexible film, each of the conductive patterns having first pads arranged on the film substrate region that are electrically connected to one of the external contact terminals and second pads arranged on the film wire region that are electrically connected to the semiconductor chip.

9. The semiconductor package of claim 8, wherein the flexible film further comprises an insulating upper layer disposed at a top of the plurality of conductive patterns and an insulating lower layer disposed at a bottom of the plurality of conductive patterns, wherein the semiconductor chip is mounted on an upper surface of the insulating upper layer.

10. The semiconductor package of claim 9, wherein each of the conductive patterns includes a first sub pattern extending toward the film substrate region, and a second sub pattern extending from the first sub pattern toward the film wire region.

11. The semiconductor package of claim 8, wherein the semiconductor chip includes a first semiconductor chip mounted on the film substrate region, and a second semiconductor chip stacked on the first semiconductor chip; and
the plurality of sub film wires include first sub film wires electrically connected to the first semiconductor chip, and second sub film wires electrically connected to the second semiconductor chip.

12. The semiconductor package of claim 11, wherein each of the conductive patterns includes a first sub pattern extending toward the film substrate region, and a second sub pattern extending from the first sub pattern toward one of the first and second sub film wires.

13. The semiconductor package of claim 11, wherein each of the plurality of conductive patterns includes a first sub pattern extending toward the film substrate region; and a plurality of second sub patterns extending from the first sub pattern, and branching out and extending toward both the first and second sub film wires.

14. The semiconductor package of claim 13, wherein the first and second semiconductor chips respectively connected electrically to the first and second sub film wires share one of the external contact terminals.

15. The semiconductor package of claim 13, wherein the first sub film wire has a shorter length than the second sub film wire.
